(19) United States
(12) Patent Application Publication
(10) Pub. No.: US 2014/0292371 A1
(43) Pub. Date: Oct. 2, 2014

(54) MULTI-THRESHOLD DUAL-SPACER DUAL-RAIL DELAY-INSENSITIVE LOGIC (MTD3L) CIRCUIT DESIGN

(71) Applicant: THE BOARD OF TRUSTEES OF THE UNIVERSITY OF ARKANSAS, (US)

(72) Inventors: Jia Di, Fayetteville, AR (US); Scott Christopher Smith, Rogers, AR (US)

(21) Appl. No.: 13/859,828

(22) Filed: Apr. 10, 2013

Related U.S. Application Data
(60) Provisional application No. 61/806,567, filed on Mar. 29, 2013.

(51) Int. Cl. H03K 19/003

(52) U.S. Cl. CPC H03K 19/00315
USPC 326/95

(57) ABSTRACT

A Multi-Threshold Dual-spacer Dual-rail Delay-insensitive Logic (MTD³L) circuit architecture. The architecture includes a first th22 circuit, a second th22 circuit, and an XNOR gate. The first th22 circuit is configured to receive a first rail input, a completion detection signal, and a reset signal, and to produce a first rail output. The second th22 circuit is configured to receive a second rail input, the completion detection signal, and the reset signal, and to produce a first rail output. The XNOR gate is configured to receive the first rail input and the second rail input and to produce a completion detection signal output.

### RELATED APPLICATION

The present patent application claims the benefit of prior filed co-pending U.S. Provisional Patent Application No. 61/806,567, filed on Mar. 29, 2013, the entire content of which is hereby incorporated by reference.

### BACKGROUND

The present invention relates to a methodology for designing secure hardware for use in cryptographic systems, which is immune to Power Analysis and Timing Analysis side-channel attacks, while having significantly less overhead than the original Dual-Spacer Dual-Rail Delay-Insensitive Logic (D³L) paradigm.

As technology advances, more and more electronic devices store secret information such as bank accounts, identification numbers, passwords, and other private data that need to be secured from unauthorized access. Although originally considered safe and secure, hardware, just as software, is prone to attacks that force the targeted system to reveal sensitive data. Cryptographic algorithms are commonly used to protect such data. However, despite the mathematical robustness of these algorithms, their physical implementations are known to be susceptible to attacks. Non-invasive attacks on such devices take advantage of side-channel information leaked from the system, instead of trying to reverse engineer it. Such side-channel information can be power, timing, electromagnetism, and any other information that might be measured from the device during computation.

Most electronic devices running cryptographic algorithms are implemented in CMOS technology, where transistors act as voltage-controlled switches. While a circuit node is switching, electrons flow across the corresponding transistors to charge/discharge its load capacitance, thereby consuming power. Due to the fact that different transistors will be turned on/off while processing different data, causing different power consumption, power-based side-channel attacks can be implemented using the IC's transient power data. These types of power-based attacks include Differential Power Analysis (DPA), and Correlation Power Analysis (CPA) (which uses the Pearson product-moment correlation coefficient to guess a key). In general, these attacks acquire transient power data while the target IC performs encryption/decryption on different texts, and then use statistical algorithms to derive the key. Power-based attacks are the most powerful and prevalently implemented side-channel attacks, and have been successfully implemented to crack almost all cryptographic algorithms on different platforms. A number of methods have been proposed for mitigating power-based attacks by decoupling transient power consumption from the data being processed. Techniques based on balancing power fluctuation include new CMOS logic gates, which go through a full charge/discharge cycle for each data processed. Other power balancing methods include modifying the algorithm execution, compensating current at the power supply node, and using subthreshold operation. Additionally, many techniques for randomizing power data have been proposed.

The principle of timing-based attacks is very similar to power-based ones except these attacks rely on timing fluctuations of the target circuit while processing different data patterns. Depending on the load capacitance and driving strength, the charge/discharge process during the switching activities at an internal circuit node will take different amounts of time to finish, which in turn causes different timing delays. Existing countermeasures include inserting dummy operations, using redundant representation, and unifying the multiplication operands.

Asynchronous circuits, especially dual-rail asynchronous circuits, possess unique characteristics that could help mitigate such attacks. Dual-rail asynchronous circuits, such as NULL Convention Logic (NCL), use two wires to represent one signal. The DATA-spacer alternation protocol ensures the number of switching of each signal to be independent from the input; instead, it is only determined by the number of data processed, making power variation significantly smaller than synchronous designs. Nonetheless, switching activity remains unbalanced between the two rails of each signal, which most likely drive different capacitive loads; thus, DPA, High-Order DPA, or CPA can still succeed. Moreover, such dual-rail logic circuits are even more vulnerable to timing-based attacks due to their strong data-timing dependency.

### SUMMARY

The invention pertains to the fields of Computer Engineering and Electrical Engineering. The invention combines Multi-Threshold NULL Convention Logic (MTNCL) and Dual-spacer Dual-rail Delay-insensitive Logic (D³L).

This invention details the design, implementation, and analysis of Multi-Threshold Dual-spacer Dual-rail Delay-insensitive Logic (MTD³L), which is capable of mitigating both power- and timing-based side-channel attacks, while requiring significantly less area and energy than the earlier D³L paradigm.

In one embodiment, the invention provides a Multi-Threshold Dual-spacer Dual-rail Delay-insensitive Logic (MTD³L) register. The register includes a first th22 circuit, a second th22 circuit, and an XNOR gate. The first th22 circuit is configured to receive a first rail input, a completion detection signal input, and a reset signal, and to produce a first rail output. The second th22 circuit is configured to receive a second rail input, the completion detection signal input, and the reset signal, and to produce a second rail output. The XNOR gate is configured to receive the first rail input and the second rail input and to produce a completion detection signal output.

In another embodiment, the invention provides a Multi-Threshold Dual-spacer Dual-rail Delay-insensitive Logic (MTD³L) circuit. The circuit includes a first circuit coupled to V_{DD}, a second circuit coupled to ground and the first circuit, the coupling to the first circuit forming a common coupling, a first pmos transistor having a source coupled to V_{DD} and a gate coupled to a sleep-to-0 input, a first nmos transistor having a drain coupled to ground and a gate coupled to a complement of a sleep-to-1 input, a second pmos transistor having a source coupled to a drain of the first pmos transistor and a gate coupled to the common coupling, a second nmos transistor having a drain couple to a source of the first nmos transistor and a gate coupled to the common coupling, a third pmos transistor having a source coupled to the drain of the first pmos transistor and a gate coupled to the complement of the sleep-to-1 input, a third nmos transistor having a drain coupled to the source of the first nmos transistor and a gate coupled to the sleep-to-0 input, and an output coupled to a drain of the second pmos transistor, a drain of the third pmos transistor, a source of the second nmos transistor, and a source of the third nmos transistor.

In another embodiment, the invention provides a Complete Multi-Threshold Dual-spacer Dual-rail Delay-insensitive Logic (MTD³L) register configured to use dual-spacer protocol and early completion checking. The Complete MTD³L register includes an MTD³L register, a first th22 circuit, a second th22 circuit, and a completion detection generator (KiGen). The MTD³L register is configured to receive a first rail input and a second rail input and to generate a first rail output and a second rail output, the MTD³L register is also configured to receive an internal completion detection signal (Ki_gen) and to generate an MTD³L register completion detection signal. The first th22 circuit is configured to receive the first rail output and the second rail output, and to generate a previous spacer (ps) output. The second th22 circuit is configured to receive a complemented external completion detection signal and the MTD³L register completion detection signal, and to generate a completion detection output (Ko). The KiGen is configured to receive the first rail output and the second rail output, the ps, and an inverted form of the completion detection output, and to generate the internal completion detection signal (Ki_gen).

Other aspects of the invention will become apparent by consideration of the detailed description and accompanying drawings.

### BRIEF DESCRIPTION OF THE DRAWINGS

FIG. 1A is a schematic diagram of a SMTNCL gate structure.

FIG. 1B is a schematic diagram of a SMTNCL TH23 implementation.

FIG. 2 is a block diagram of a Slept Early Completion and Registration Input-Incomplete (SECRII) architecture.

FIG. 3 is a graph of D³L switching activity.

FIG. 4 is a schematic diagram of a D³L input complete AND function.

FIG. 5 is a block diagram of a complete D³L register.

FIG. 6 is a schematic diagram of the KiGen circuit.

FIG. 7 is a block diagram of a D³L register.

FIG. 8 is a schematic diagram of a spacer filter.

FIG. 9 is a block diagram of a D³L filter register.

FIG. 10 is a schematic diagram of a ps signal delay component.

FIG. 11 is a block diagram of a D³L spacer generator register.

FIG. 12 is a schematic diagram of a D³L spacer generator.

FIG. 13A is a schematic diagram of a first MTD³L gate structure.

FIG. 13B is a schematic diagram of a first MTD³L TH23 gate implementation.

FIG. 14A is a schematic diagram of a second MTD³L gate structure.

FIG. 14B is a schematic diagram of a second MTD³L TH23 gate implementation.

FIG. 15 is a schematic diagram of an MTD³L register.

FIG. 16 is a block diagram of a complete MTD³L register.

FIG. 17 is a block diagram of an MTD³L spacer filter register.

FIG. 18 is a block diagram of an MTD³L spacer generator register.

FIG. 19 is a block diagram of an MTD³L ring register.

FIG. 20 is a top level diagram of an AES core.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

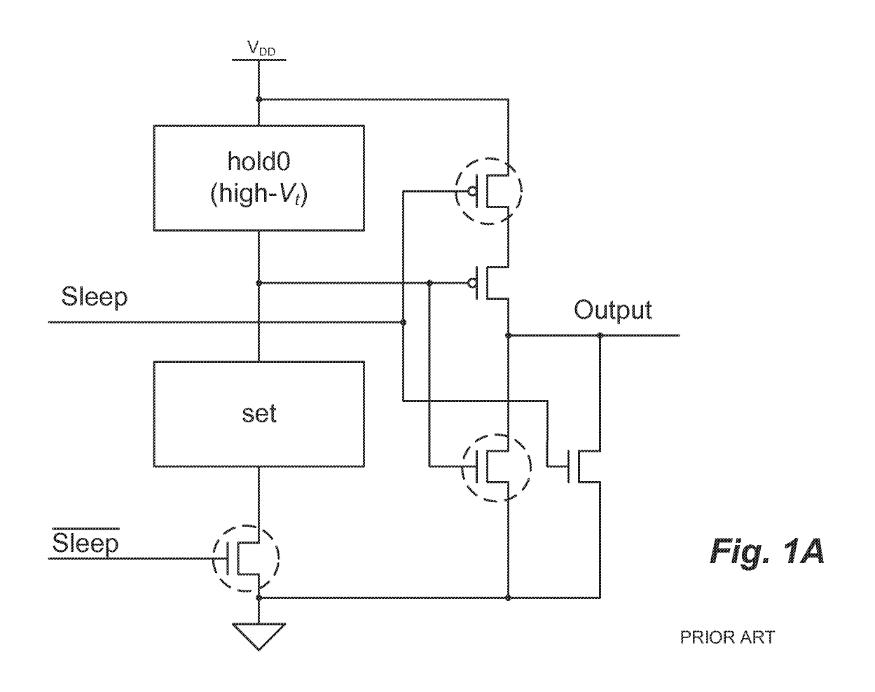

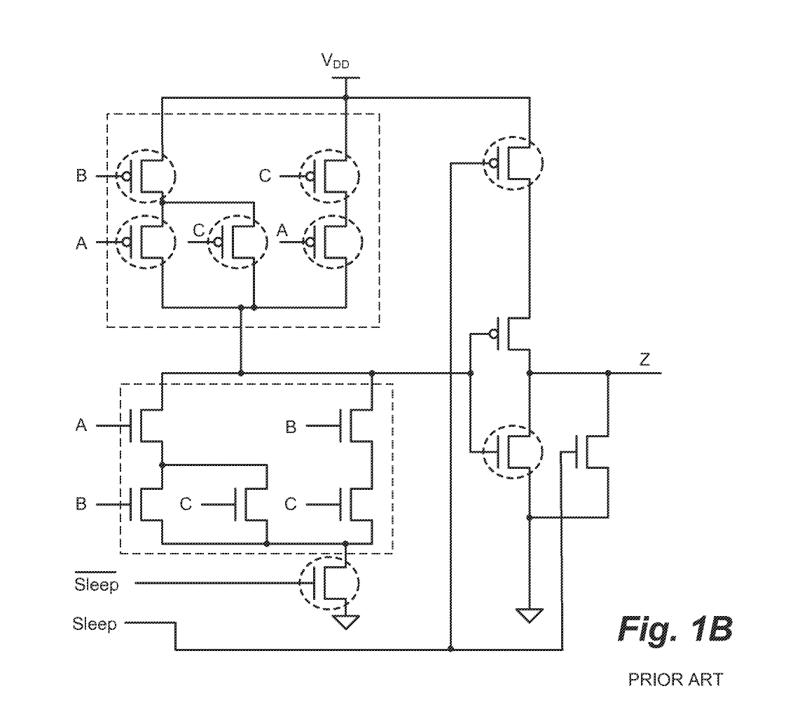

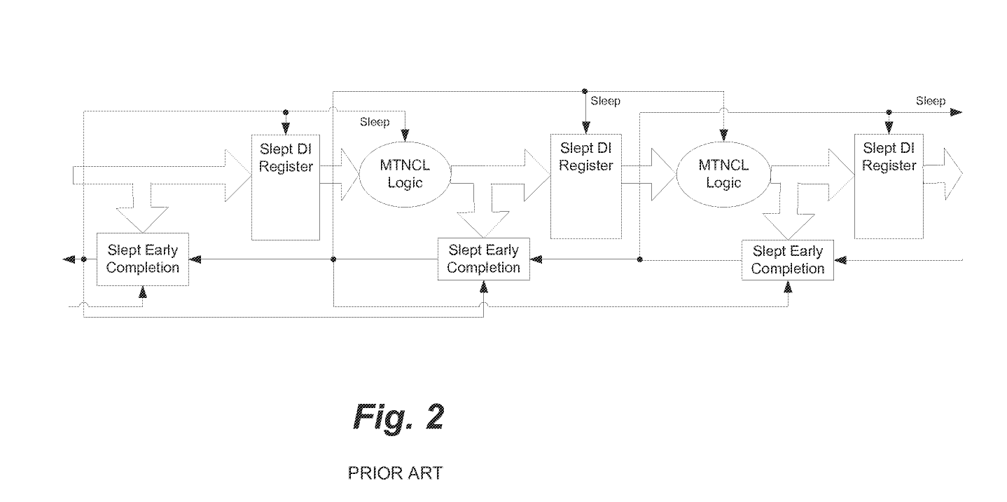

MTNCL circuits utilize a sleep signal to simultaneously force all circuit elements to NULL instead of propagating a NULL input through the circuit, as described in U.S. Pat. No. 7,977,972 (the '972 Patent), the entire content of which is hereby incorporated by reference. This allows for the MTNCL gates to no longer require state-holding hysteresis logic and for the MTNCL combinational logic circuits to no longer need to be input-complete and observable, both of which significantly reduce area and power/energy, while increasing speed. An Static MTNCL (SMTNCL) gate and a Slept Early Completion and Registration Input-Incomplete (SECRII) architecture are shown in FIGS. 1 and 2, respectively; and are both described in the '972 Patent.

Dual-spacer Dual-rail Delay-insensitive Logic is an extension of the NULL Convention Logic (NCL) style that utilizes a dual-spacer protocol, as opposed to NCL's single spacer protocol. The motivation for this is the elimination of imbalanced switching activity on the two encoding wires of a data bit. By balancing this switching activity, data is further decoupled from the power consumption of the circuit, providing robustness against power analysis attacks.

TABLE 1
D³L ENCODING SCHEME

| State | Rail 0 | Rail I |
|---|---|---|
| All-Zero Spacer | 0 | 0 |
| Data 0 | 1 | 0 |
| Data 1 | 0 | 1 |
| All-One Spacer | 1 | 1 |

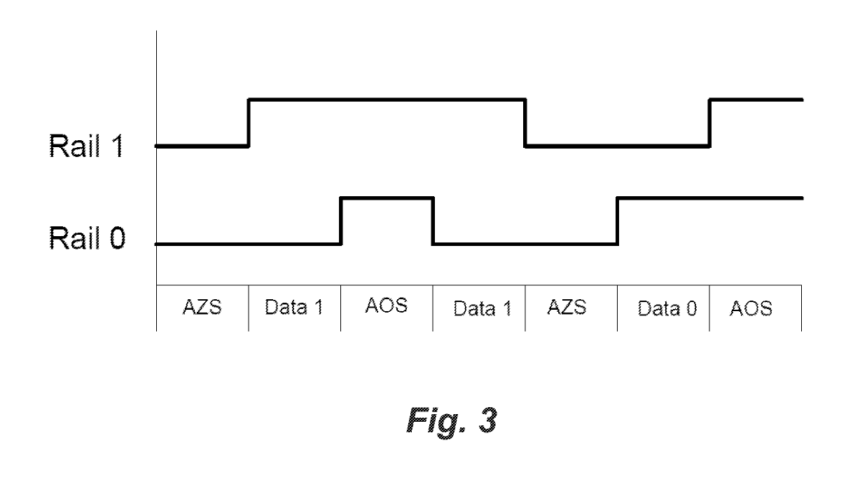

Table 1 shows the D³L encoding scheme. Like NCL, the DATA and NULL states remain the same. However, the NULL state is now called the All-Zero Spacer (AZS). The former invalid state, where both rails are asserted, is now the All-One Spacer (AOS). The AZS and AOS are alternated between spacer cycles, implementing a dual-spacer protocol. As a result, the switching activity over a complete set of Data/Spacer cycles is balanced on both rails, as shown in FIG. 3.

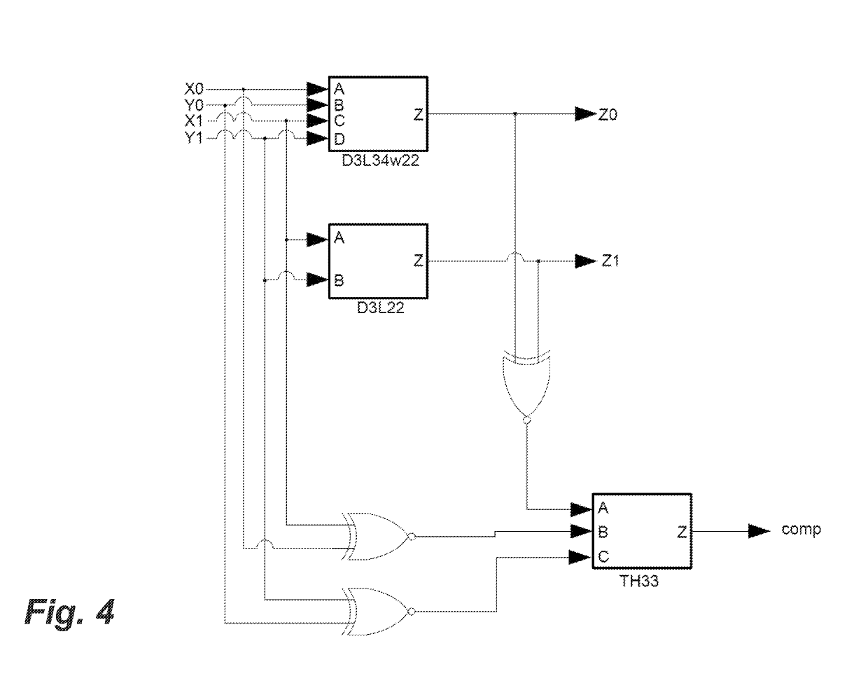

The D³L threshold gates are modified versions of the NCL threshold gates. As such, a complete set of 27 NCL functions can be implemented in D³L. While NCL gates use hysteresis, D³L gates are unable to do so to accommodate the dual-spacer protocol. As such, D³L threshold gates are smaller than NCL threshold gates due to the omission of the hysteresis transistors. The removal of hysteresis, however, means that D³L gates are unable to guarantee input completeness. Instead, an NCL_X technique is used to provide input completeness. This technique adds additional logic to D³L functions that check the inputs and outputs of the function, creating a completion signal. Since the spacer cycles in D³L occur when data rails are the same, an XNOR gate can be used to detect them. The outputs from these XNOR gates go to a THnn gate, which acts as a C-element. The resulting completion signal is checked along with the usual handshaking protocol to ensure that the logic is ready for the next wavefront. A downside to this technique, however, is the overhead incurred by adding large amounts of XNOR and threshold gates to the design to ensure input-completeness. An input-complete D³L AND function is shown in FIG. 4.

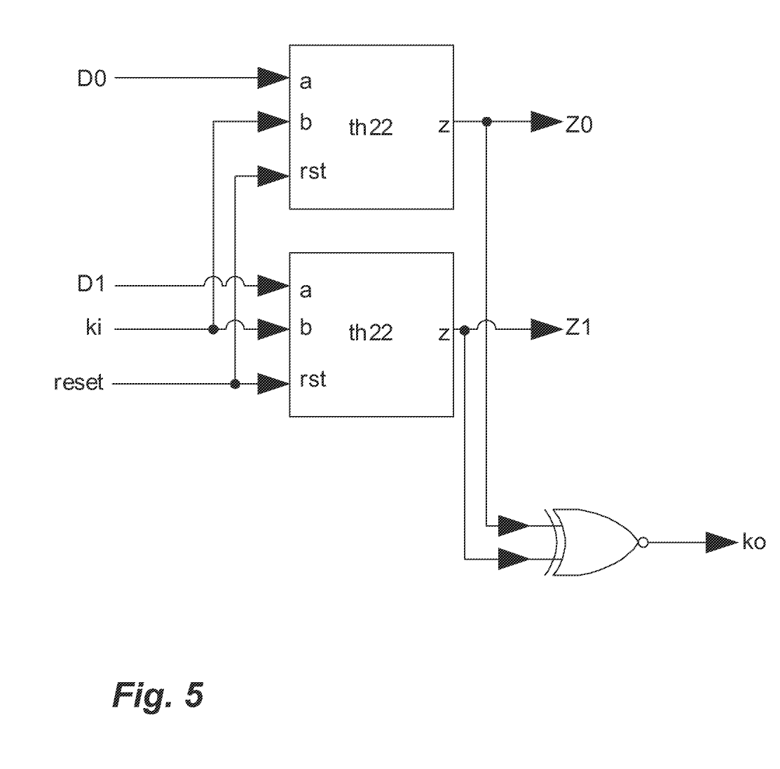

The basic D³L Register, shown in FIG. 5, is a modified NCL register. It includes two TH22 gates which are resettable to the desired value. An XNOR gate facilitates completion detection signal (KO) generation by checking the relative values of the register's outputs. As mentioned previously, the XNOR gate is required to detect both AZS and AOS.

Additional logic is required to facilitate the dual-spacer protocol. NCL registers require a NULL input before they are able to accept new data. They will not recognize an all-one spacer. To fix this, extra logic (e.g., a Ki generator), which is capable of recognizing the all-one spacer, is used to control the register's early completion input (Ki). This Ki Generator has four inputs: a Ki, a previous spacer (ps), and dual-rail outputs of the register. The value of ps is generated by a resettable TH22 gate. This value is logic 0 for an all-zero spacer and logic 1 for an all-one spacer. The ps gate and the register must be reset to the same value. If the register is reset to DATA then the ps gate is reset to logic 0. The Ki Generator's output follows the Boolean equation

Ki_{—}gen= K̅I̅ p̅s̅(Z0+Z1)+KIps( Z̅0̅+ Z̅1̅)+ Z̅0̅ Z̅1̅KI+Z0Z1 K̅I̅

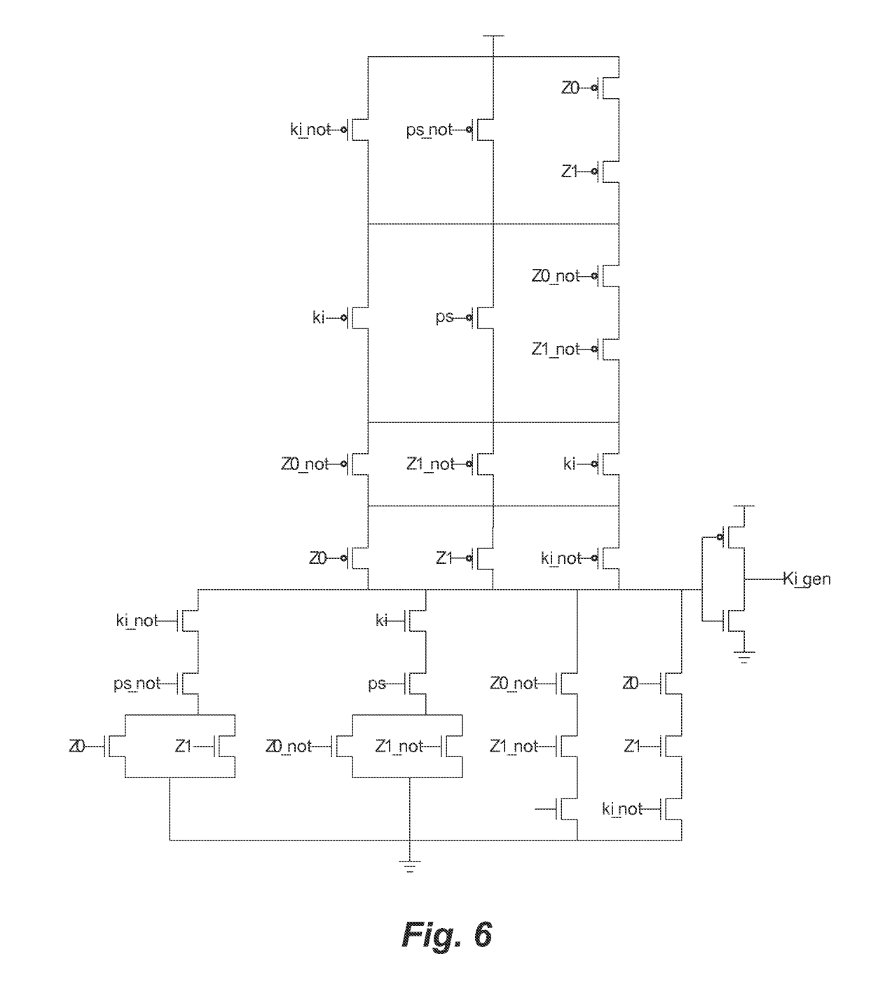

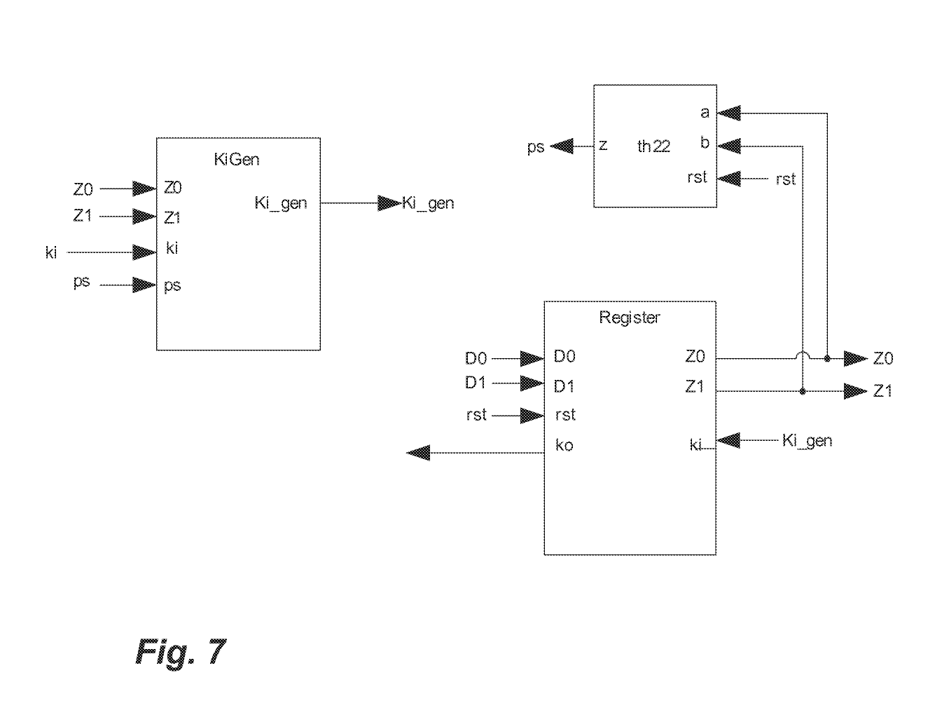

which results in the truth table shown in Table 2, and the transistor implementation shown in FIG. 6. If an all-one spacer is needed then the value of Ki_gen will be changed to logic 1 allowing the register to latch it. Once the next data value arrives, Ki_gen will switch to logic 0. As a result, one of the register's TH22 gates will have two low inputs which will change its output to logic 0, latching the data. A complete D³L register is shown in FIG. 7.

TABLE 2
KIGEN TRUTH TABLE

| Row | Z0 | Z1 | Ki | ps | Ki_gen |
|---|---|---|---|---|---|
| 1 | 0 | 0 | 0 | 0 | 0 |
| 2 | 0 | 0 | 0 | 1 | 0 |
| 3 | 0 | 0 | 1 | 0 | 1 |
| 4 | 0 | 0 | 1 | 1 | 1 |
| 5 | 0 | 1 | 0 | 0 | 1 |
| 6 | 0 | 1 | 0 | 1 | 0 |
| 7 | 0 | 1 | 1 | 0 | 0 |
| 8 | 0 | 1 | 1 | 1 | 1 |
| 9 | 1 | 0 | 0 | 0 | 1 |
| 10 | 1 | 0 | 0 | 1 | 0 |
| 11 | 1 | 0 | 1 | 0 | 0 |
| 12 | 1 | 0 | 1 | 1 | 1 |
| 13 | 1 | 1 | 0 | 0 | 1 |
| 14 | 1 | 1 | 0 | 1 | 1 |
| 15 | 1 | 1 | 1 | 0 | 0 |
| 16 | 1 | 1 | 1 | 1 | 0 |

While the D³L register is capable of handling the dual-spacer protocol, it is insufficient to implement ring register configurations. This is because a basic D³L register is incapable of generating alternating spacers. Instead, the same spacer would pass through the ring twice causing deadlock. A modified filter register is required for generating alternating spacers. A D³L Filter register is a basic D³L register with a spacer filter operating on the register's inputs.

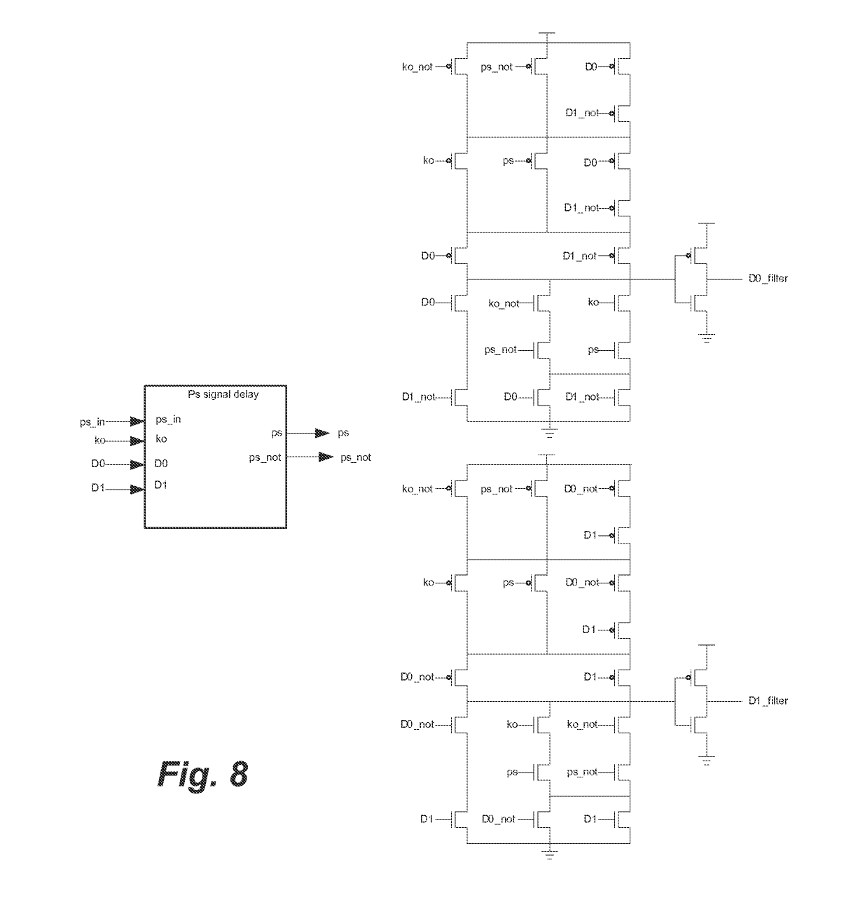

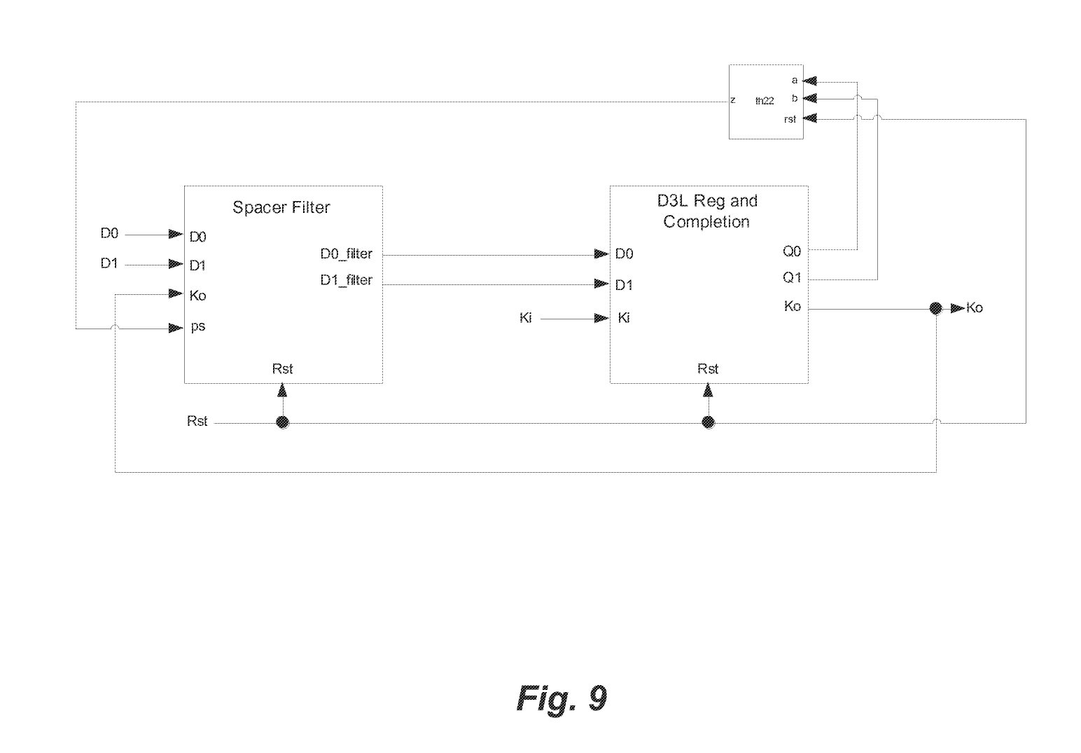

The spacer filter monitors the dual-rail input, the previous spacer, and the Ko from the register to ensure that spacers are alternated as they pass through. In a typical ring register configuration, the first two registers would be normal D³L registers reset to NULL and a filter register reset to DATA0 or DATA1. When the filter register receives an all-one or all-zero spacer it outputs the alternate spacer. This ensures that the same spacer does not pass through the ring twice. FIG. 8 shows a transistor schematic of a spacer filter. FIG. 9 shows a filter register diagram. The spacer filter's outputs are based on the following equations:

D0_filter=D0 D̅1̅+ K̅0̅ p̅s̅D0+K0psD0+K0ps D̅I̅+ K̅1 p̅s̅ D̅1

D1_filter= D̅0̅D1+ K̅0̅ p̅s̅D1+K0psD1+K0ps D̅0̅+ K̅0̅ p̅s̅ D̅0̅

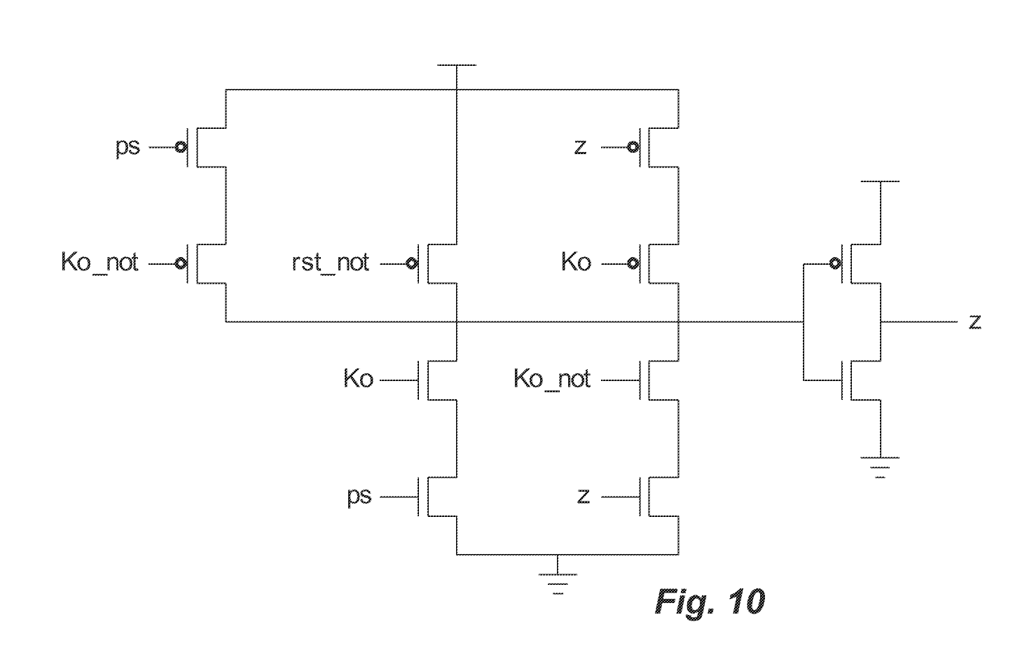

The ps signal delay component used in the filter, shown in FIG. 10, prevents ps from changing unless the register's Ko is logic 1, i.e., requesting DATA. This ensures that the value of ps is only changed once the register receives the spacer.

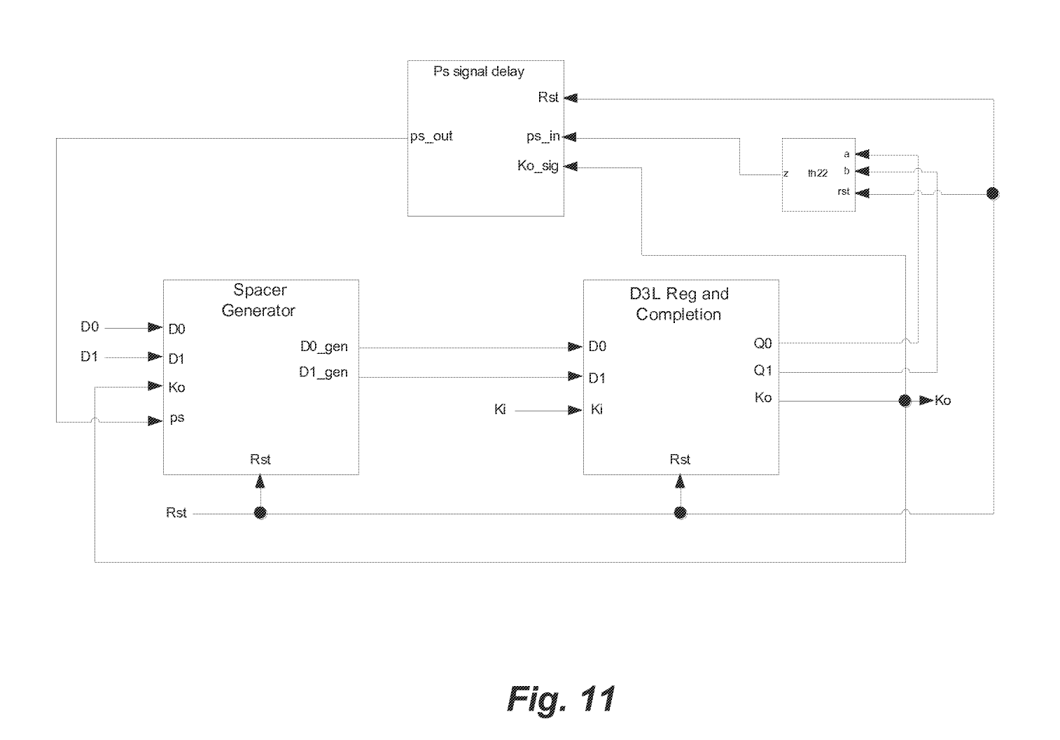

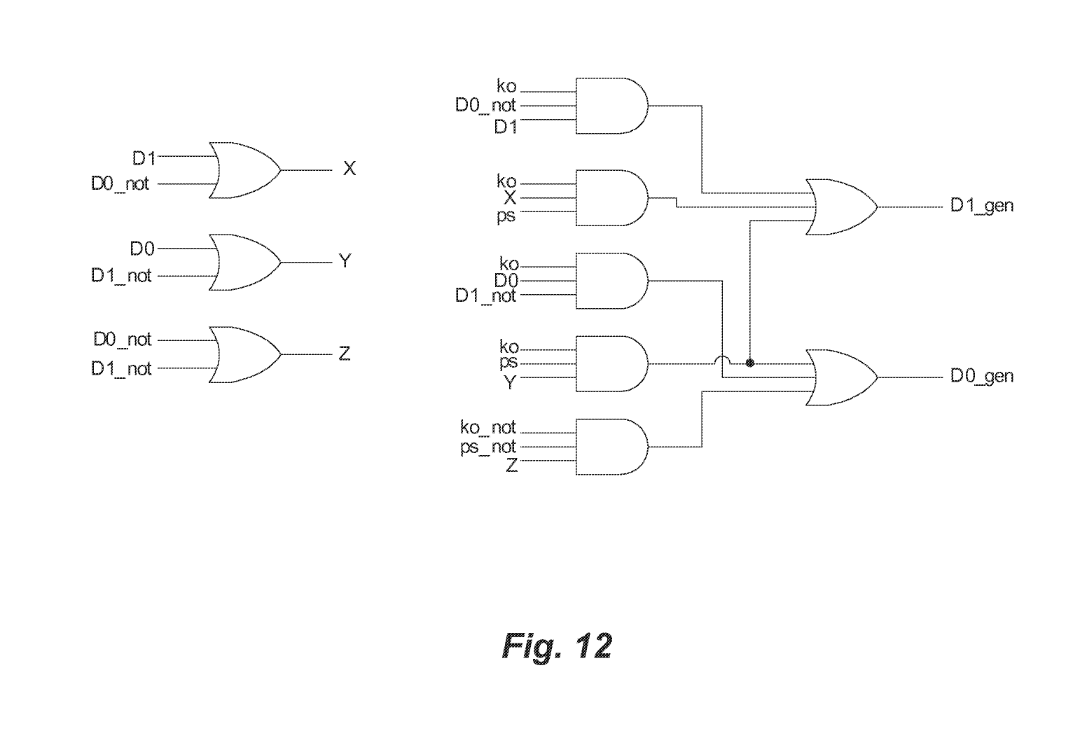

In situations where a component needs many cycles to output data but does not have input provided for each cycle, the component will not be able to receive the spacers it needs as input. Instead, a spacer generator register is used to generate these spacers for the component. A spacer generator register is a basic D³L register with a spacer generator sitting between it and its inputs. The spacer generator keeps track of the previous spacer and generates the alternate spacer when requested regardless of the dual-rail input it receives. For example, if the previous spacer was an all-zero spacer and the register requests a spacer, the spacer generator will generate an all-one spacer. The next time a spacer is requested, it generates an all-zero spacer. FIG. 11 shows the Spacer Generator Register. FIG. 12 shows the Spacer Generator Diagram. The outputs of the spacer generator are given by the following equations:

D0_gen= K̅0̅ p̅s̅(D0+D1)+Kops(D0+ D̅1)+K0D0 D̅1̅

D1_gen= K̅0̅ p̅s̅(D0+D1)+KOps( D̅0̅+D1)+K0 D̅0̅D1

Although the D³L scheme successfully implements the dual-spacer protocol, it suffers from high overhead compared to equivalent NCL designs. This overhead comes from two sources. The first is the required NCL-X style completion logic in the form of several XNOR gates attached to each logic function. The second is the more complex registration. To eliminate the first source of overhead, the MTNCL technique can be applied.

Because D³L gates do not use hysteresis, an external source is required for input completion detection. Rather than using XNOR and threshold gates, the early completion technique can be used. As explained above, the early completion technique ensures that requests for a spacer will only be generated when all circuit inputs are that spacer and the following stage is requesting a spacer. At this point, the combinational logic can be slept to the proper value, ensuring input-completeness. Thus, the need for extra completion checking logic is eliminated.

No modification to the D³L logic is required to add sleep logic to a D³L gate because it already matches the form of the modified NCL gates used in the MTNCL technique—a hold0 block and a set block. The only modification required is the addition of the sleep transistors. The sleep-to-0 transistors can be used in the same way as in SMTNCL. These transistors are responsible for the all-zero spacer transition. A similar set of transistors can be used for the all-one spacer transition.

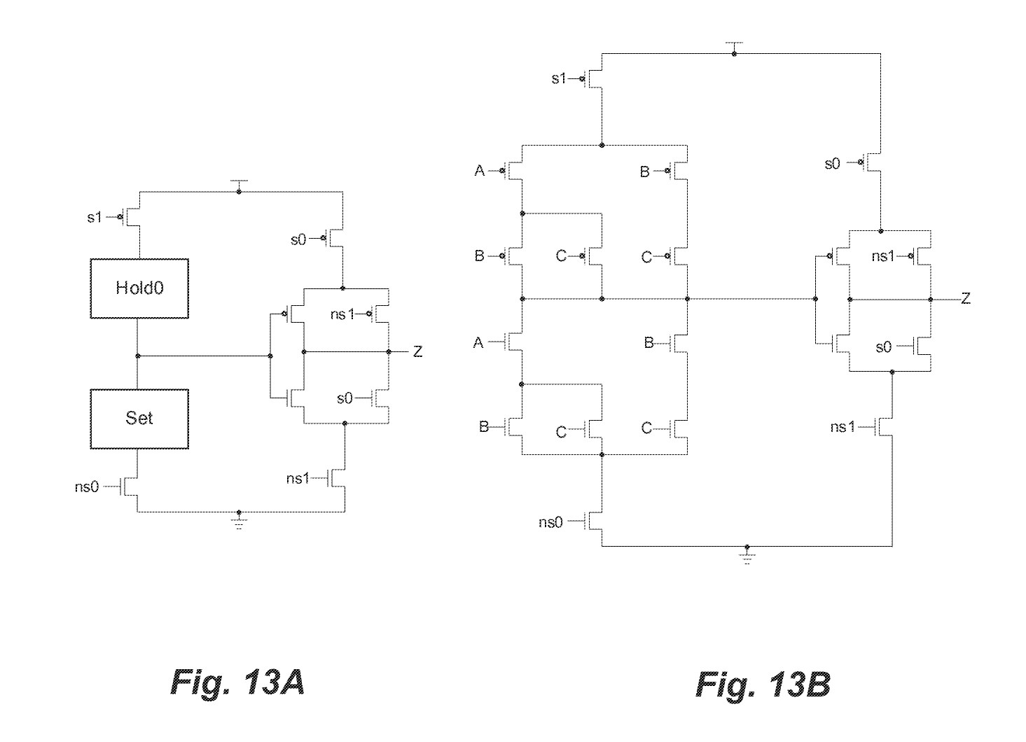

The sleep transistors are controlled by a pair of sleep signals, sleep-to-0 (s0) and sleep-to-1(s1), and their complements, as shown in Table 3. These signals should not be asserted at the same time. Instead, if either of the inputs is asserted, the circuit will be slept to the appropriate value. FIG. 13 shows the MTD³L gate design. When s0 is asserted, the circuit is slept to the all-zero state. In this case, the NMOS transistor parallel to the output inverter is turned on, the NMOS transistor gating the main circuit to ground is turned off, and the PMOS transistor gating the output circuit to V_{DD} is turned off. Additionally, since s1 is off, the NMOS transistor controlled by nsl is turned on, completing the path from the output to ground, forcing the output to logic 0. The PMOS transistor controlled by s1 is also turned on, allowing the main circuit to pass an output of 1 to the output inverter, preventing glitches from occurring when s0 is later asserted. When this happens, the output inverter will have logic 1 on its input, so it will continue to output logic 0 until new data has arrived. Similarly, when s1 is asserted, the circuit is slept to the all-one state. The path to V_{DD} for the main circuit is turned off while the path to ground remains on, allowing a 0 to eventually reach the output inverter. The output inverter's path to ground is cut off and a direct path to V_{DD} is formed, forcing the output to be logic 1. When the sleep-to-1 state ends, the output inverter will have logic 0 on its input so the output will remain at logic 1, preventing a glitch. If neither sleep signal is asserted, the circuit operates as it would normally. All four power- and ground-gating transistors are turned on, allowing normal access to power and ground for the circuit and output inverter. The two parallel output transistors are turned off, so the output is only controlled by the output inverter. If both sleep signals happen to be asserted at once, the four power- and ground-gating transistors will be turned off, leaving the circuit in a floating state; however, this will never occur in a properly operating circuit.

TABLE 3
MTD³L SLEEP SIGNALS

| S0 | S1 | Output |
|---|---|---|
| 0 | 0 | Normal |
| 0 | 1 | All-One Spacer |
| 1 | 0 | All-Zero Spacer |
| 1 | 1 | Invalid |

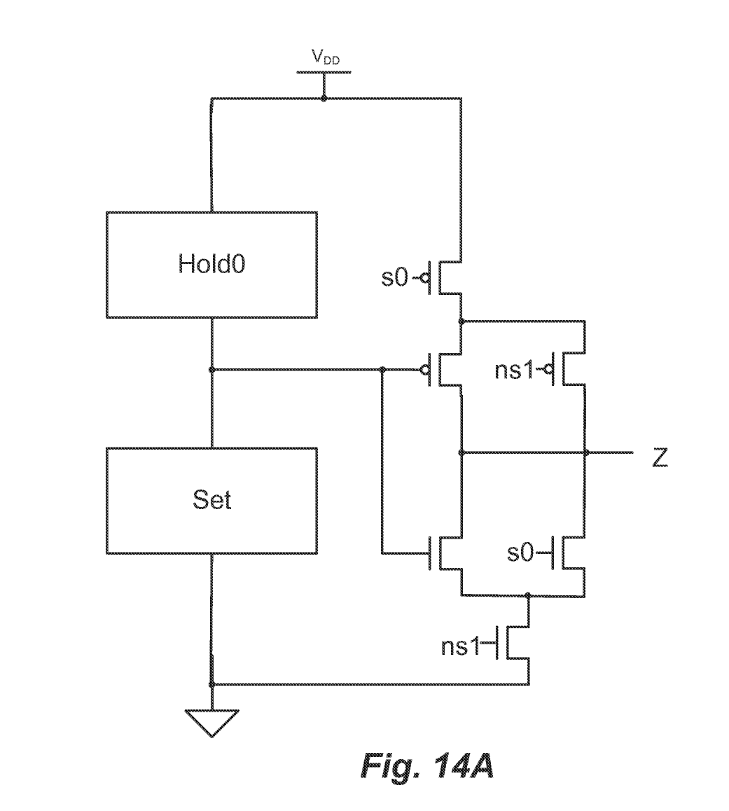

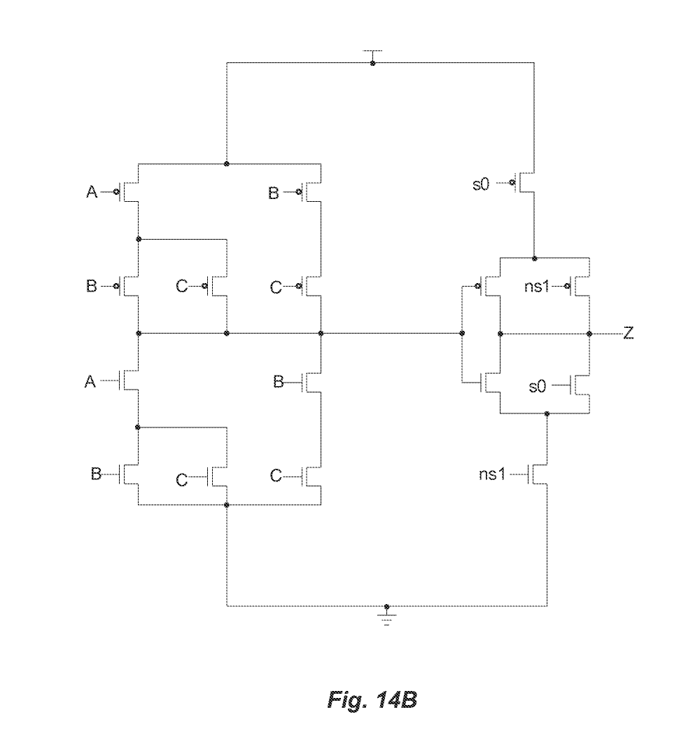

One of the drawbacks of this design is the potential for very large fanouts on the sleep signals. If the design is coarsely pipelined or the combinational logic happens to be very large, a single set of sleep signals may have to service thousands of gates, requiring these signals to be heavily buffered. Not only must s0 and s1 be buffered but their complements will require buffering as well. To mitigate this issue and to reduce the number of inputs to these gates in general, a modified design may be used to eliminate the need for the complemented sleep signals, as shown in FIG. 14. This design removes the power- and ground-gating transistors from the main circuit, leaving only the four transistors on the output inverter. These four transistors are controlled by s0 and the complement of s1, allowing for the removal of s0's complement and s1 itself. Thus, only two signals must be buffered instead of four. The drawback to this technique is the main circuit is directly exposed to power and ground, eliminating the ability to gate the circuit with high-V, transistors

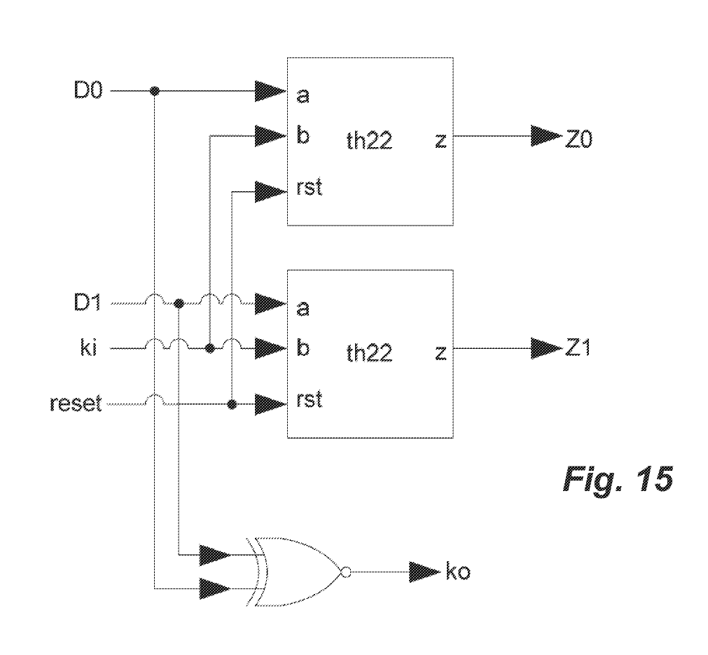

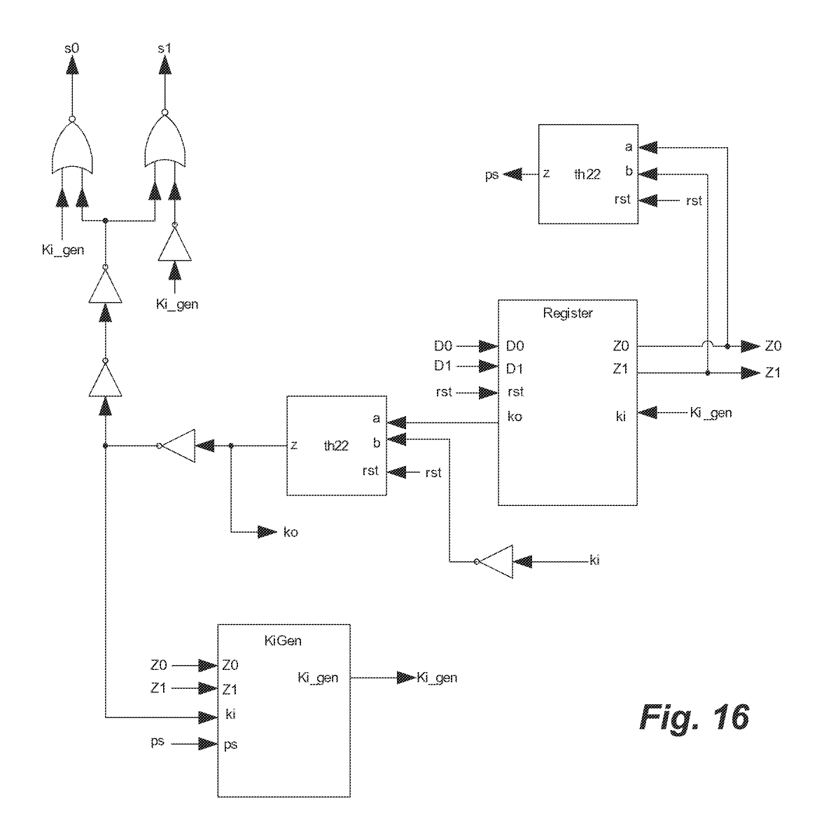

A basic MTD³L Register, shown in FIG. 15, is a modified NCL register. It consists of two TH22 gates which are resettable to the desired value. An XNOR gate facilitates early completion by checking the relative values of the register's inputs. If both input rails have the same value then the register has received a spacer and will request for data. If the values are different, then DATA has been received so the register will request the next spacer.

Additional logic is required to facilitate the dual-spacer protocol and early completion checking. The early completion component consists of resettable TH22 gates whose inputs are the register's Ko and the next stage's inverted Ko. The reset state of the early completion component is logic 1 if the register's reset state is NULL and logic 0 if the register's reset state is DATA. In order to ensure input-completeness, the early completion Ko is inverted before being passed back as the register's Ki input. This prevents a partial spacer wavefront from passing through the register by ensuring that all of the register's inputs are an all-zero or all-one spacer before the spacer wavefront is allowed to pass through the register. In order to facilitate the dual-spacer protocol, the same Ki Generator used in D³L registration, shown in FIG. 6, is used for MTD³L.

If the register needs to supply sleep signals, then sleep signal logic is used here as well, as shown in FIG. 16. This logic generates two sleep signals, s0 and s1. The values of the sleep signals are shown in Table 4. If the register's Ki is 0 then a spacer is being requested. To determine which spacer is being requested, Ki_gen's value is used. If Ki_gen is logic 0 then an all-zero spacer is being requested; if it is logic 1 then an all-one spacer is being requested. To avoid incorrect sleep states, a buffer is used as a delay element to ensure that the change in Ki_gen's value is evaluated first. For example, if the desired change were from the no sleep state of row 2 to the sleep-to-lstate of row 3 then both Ki_gen and Ki will switch. If Ki switches first, a sleep-to-0 will be issued erroneously. However, if Ki_gen switches first then the no sleep state will be maintained until Ki changes as well, resulting in the correct sleep-to-lstate.

TABLE 4
MTD³L SLEEP SIGNAL SWITCHING SEQUENCE

| Ki_gen | Ki | S0 | S1 |
|---|---|---|---|
| 0 | 0 | 1 | 0 |
| 0 | 1 | 0 | 0 |
| 1 | 0 | 0 | 1 |
| 1 | 1 | 0 | 0 |

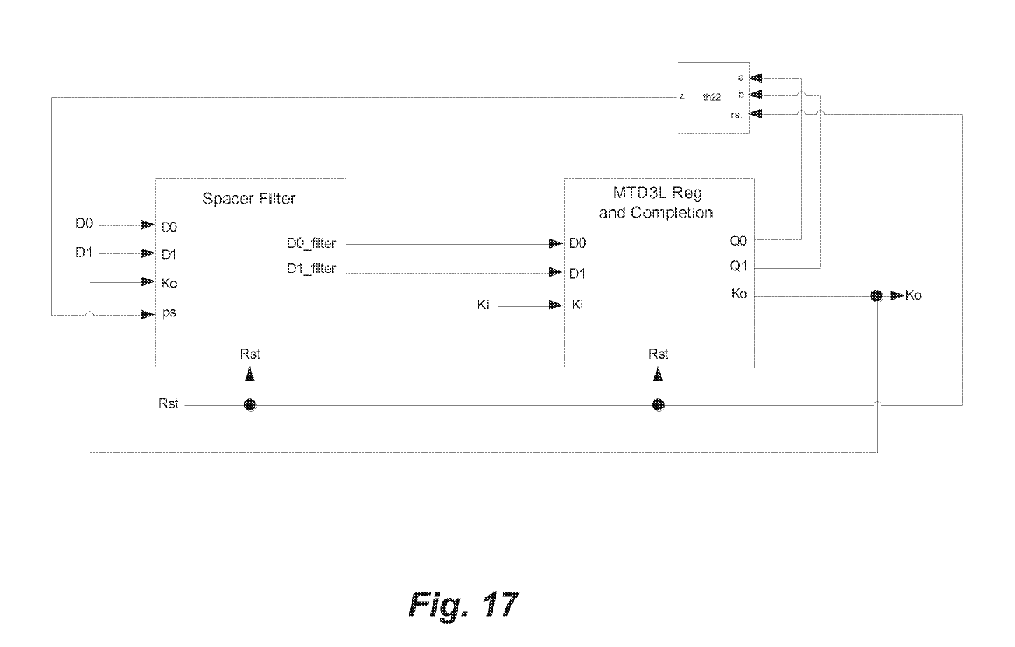

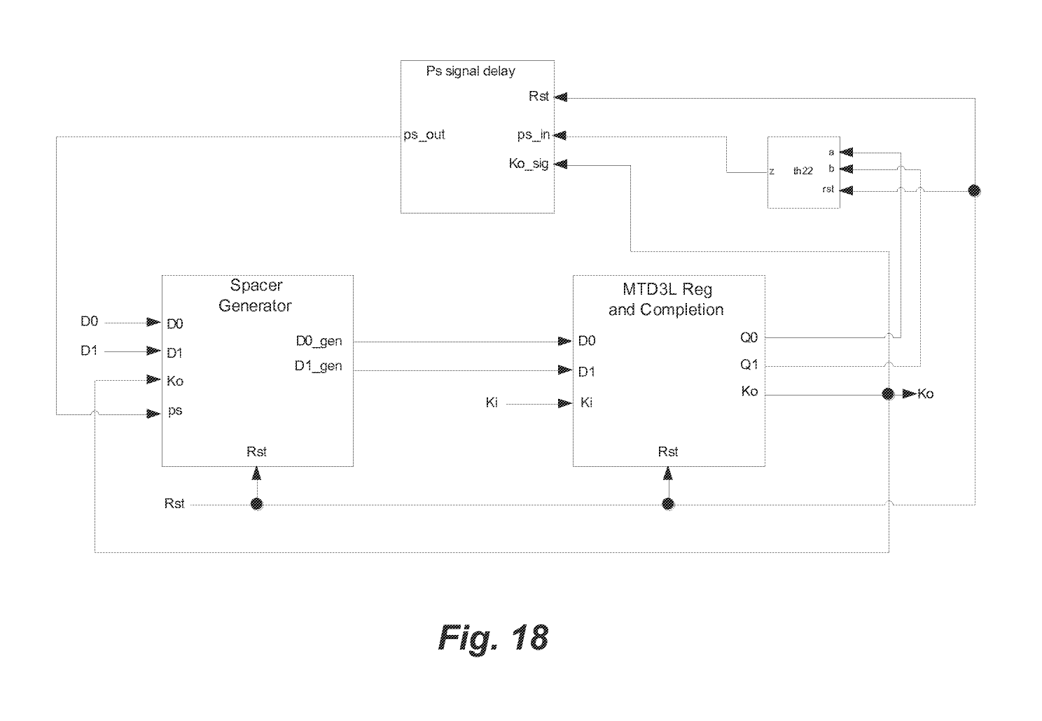

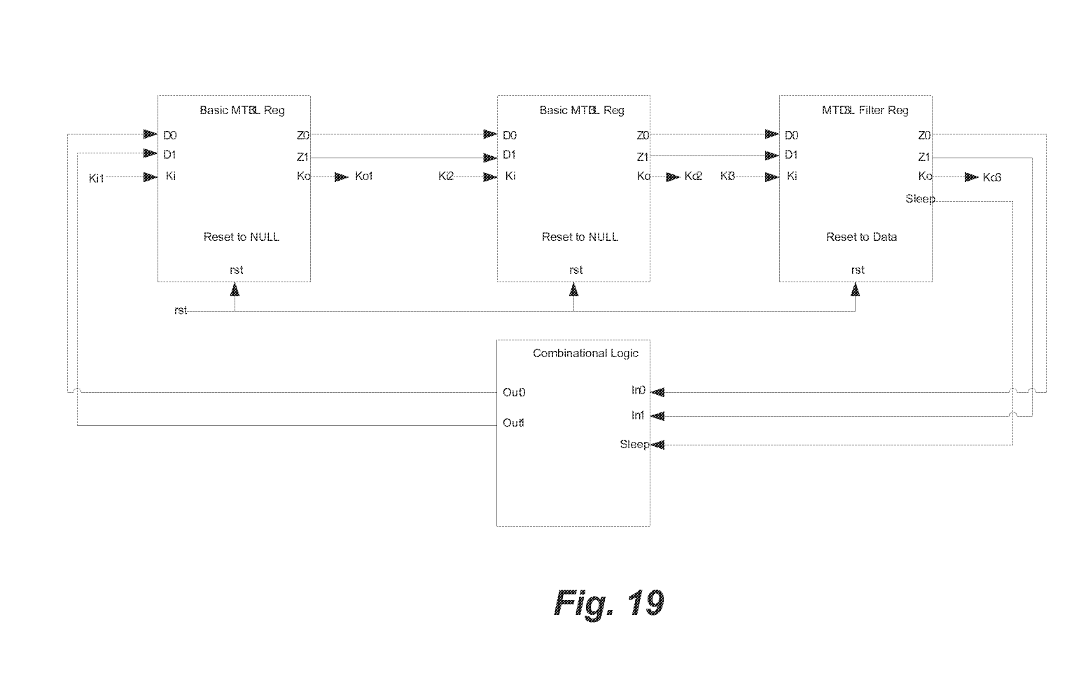

Spacer Filter and Spacer Generator registers, shown in FIGS. 17 and 18, respectively, are used in the same manner as they are used in D³L circuits. The Filter register is used as the final register in a register ring, shown in FIG. 19. It is reset to DATA and filters the spacer that passes through the ring, alternating it so that the dual-spacer protocol is enforced. The Spacer Generator generates the appropriate spacer as needed regardless of the values of its inputs.

Typically, these registers are the ones that generate sleep signals as they are usually the registers that are facing combinational logic as shown in FIG. 19. The actual Spacer Filter and Spacer Generator components are unmodified from their D³L counterparts, shown in FIGS. 8 and 12, respectively.

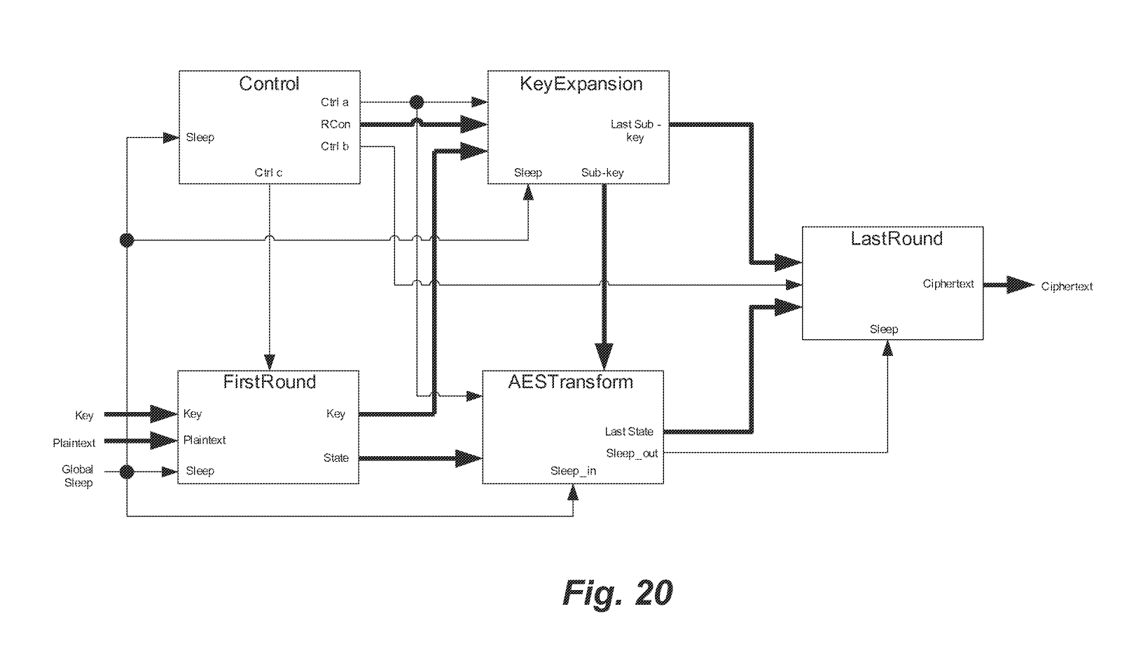

The implementation of an Advanced Encryption Standard (AES) core in MTD³L is shown in FIG. 20. The AES transform and key expansion functions are computed in parallel. A control block synchronizes the two functions and ensures that the correct sub-key is sent to the transform block. To outside, this circuit behaves as a register in terms of handshaking, so it can be easily integrated into an asynchronous system. Although the AES core accepts an input and produces an output within one external DATA/spacer cycle, it actually undergoes several internal cycles for processing each plaintext.

As shown in FIG. 20, the FirstRound block is a set of input registers that latch in new data and provide it to the AESTransform and KeyExpansion blocks. The AESTransform block performs the ciphertext calculation for each round of the algorithm. The KeyExpansion block calculates the subkey used in the AESTransform block. The Control block creates the control signals as well as generates the RCon constant which is used in the KeyExpansion block. The LastRound block performs the final round of calculations and also has a set of output registers to hold the final ciphertext. The communication among these blocks consists of multiple handshaking signals generated by manipulating the KO values from each block. The sleep signal generation mechanism consists of two types of sleep signals: a global sleep and local sleeps. The global sleep, which is a primary input, is to sleep the entire circuit between encryption stages. This sleep is only asserted after the ciphertext is latched by the subsequent circuit and the external handshaking is requesting for spacers. The internal sleep signals are generated locally within each block by the corresponding registers. These signals are asserted between logic stages. The LastRound block uses the sleep signals generated by the AESTransform block.

The D³L design is very similar to the MTD³L implementation in terms of architecture. The same five blocks are used and their configurations are essentially the same. There are two primary differences between the two designs. First, since the D³L design lacks sleep signals, a global reset is used to reset the spacer-generator registers in the FirstRound block between encryptions. This reset is required for the circuit to function properly. The second difference is the usage of completion signals. Each combinational block has a completion signal used to ensure input completeness, as required by the NCL_X architecture.

An AES core was designed using NCL, D³L, MTD³L, and the traditional synchronous methodology, to compare the various implementations in terms of energy consumption, speed, area, and side-channel attack resistance. Each AES design was implemented at the transistor level using Cadence and the IBM 8RF-DM 130 nm process. The full AES designs were used for the collection of energy, speed, and area data. All simulations were done using the Cadence UltraSim simulator. Each design was simulated using the input key 0x2b7e151628aed2a6abf7158809cf4f3c.

Because a complete evaluation of the D³L and MTD³L designs requires two spacer cycles, each simulation covered two complete encryptions. For the synchronous design, the simulation begins with the circuit in its reset state. Next, the key and plaintext are given and the circuit operation continues until the ciphertext is received. On the next clock cycle, a second plaintext is entered and the second encryption cycle completes. The energy and speed of the design is calculated from the reset state until the time of completion for the second encryption. The synchronous design is controlled using vector files. The NCL, D³L, and MTD³L designs, being asynchronous, are more difficult to simulate using vector files, due to the difficulties in anticipating when the handshaking signals should be changed. Thus, the asynchronous designs are simulated using controllers defined with VerilogA, which monitors the outputs of the design and makes adjustments to the design's inputs accordingly. The NCL simulation begins in a NULL state. The first plaintext is passed followed by another NULL state. Once this cycle completes, a second plaintext is given followed by the third NULL state. The energy and speed data is calculated from the initial state through the end of the second DATA-NULL pair. The D³L and MTD³L simulations are similar, following the pattern of AZS-DATA-AOS-DATA-AZS.

As shown in Table 5, the synchronous design is the fastest. The NCL design is the slowest and the MTD³L and D³L designs are in the middle. The D³L design uses the most energy followed by the MTD³L design and the NCL design. As explained previously, the D³L design suffers from significant overhead problems, which can be seen in these results, particularly with respect to energy consumption. The purpose of the MTD³L design was to reduce this overhead to more reasonable levels. In this respect, the MTD³L design has a 36% reduction in energy consumption over the D³L design.

TABLE 5
SPEED AND ENERGY RESULTS

| | | % speed over | | % energy over |
|---|---|---|---|---|
| | | Synchronous | Energy | Synchronous |
| Design | Delay (ns) | design | (nJ) | design |
| Synchronous | 153 | 0% | 1.356 | 0% |
| NCL | 462 | 302% | 2.208 | 163% |
| D³L | 325 | 212% | 6.012 | 443% |
| MTD³L | 330 | 216% | 3.84 | 283% |

Table 6 presents the area of each design after cell placement in Synopsys Astra. The MTD³L design sees significant overhead reduction compared to the D³L design. This can be attributed to the removal of the NCL_X style completion logic. With this overhead reduction, the MTD³L area is comparable to that of the NCL design.

TABLE 6
CIRCUIT AREA

| Design | Width (um) | Height (um) | Total Area (mm²) |
|---|---|---|---|
| Synchronous | 1227 | 1223 | 1.50 |
| NCL | 1812 | 1809 | 3.28 |
| D³L | 2503 | 2503 | 6.27 |
| MTD³L | 1835 | 1838 | 3.37 |

Because of the long simulation times required for the full designs, data collection for the power and timing attacks were performed with sub-circuits of each design. This is because each of these attacks requires many different simulation samples (256 samples in this case) to be successful. This number of simulations with the full designs would be impractical. The sub-circuits consist of the initial Addround and Subbyte stage of each design. This is because the Subbyte operation is the most vulnerable point to side-channel attacks. The attacks themselves focus on only one S-box of the Subbyte block, brute forcing all 256 plaintext input combinations of that S-box and attempting to extract one byte of the cipher key. It is assumed that if one byte of the key can be extracted then the other 15 bytes can be obtained as well. While UltraSim in Cadence was used for the full simulations, it was found that Synopsys Nanosim could perform simulations in less time. Because so many simulation samples were required for the side-channel attacks, Nanosim was used to collect this information rather than Ultrasim. The power and timing attacks were carried out with a Java program. The program takes the simulation data and a statistical model of the design as input.

Table 7 shows the results of the power- and energy-based attacks. The highest correlation out of the set of key guesses is shown for each design in as well as if the highest correlation guess was generated by the correct key value. For the timing attacks against the asynchronous designs, which were each partitioned into several parts, only the part that resulted in the highest correlation is given. For example, the MTD³L timing attack had the highest result for the first data to AOS transition, so only that result is given. All other MTD³L transitions resulted in lower correlations. The synchronous and NCL attacks were successful while the D³L and MTD³L attacks were not. The synchronous design, having no defense against power analysis, resulted in the highest correlation coefficient. This means that the key guess for this design has the most confidence. The D³L and MTD³L coefficients were very similar. This is expected because the changes from the D³L design to the MTD³L design should not have impacted the MTD³L design's side-channel defenses.

TABLE 7
POWER ANALYSIS RESULTS

| | | Correlation | Correct Key Guess |
|---|---|---|---|
| Design | Attack Type | Coefficient | Success/Failure |
| Synchronous | Power | 0.668 | Success |
| NCL | Energy | 0.428 | Success |
| D³L | Energy | 0.354 | Failure |
| MTD³L | Energy | 0.353 | Failure |

Table 8 shows the results of the time-based attacks. Again, the MTD³L design performed very similarly to the D³L design. These results show that only the D³L and MTD³L designs are resilient to both power-based and timing-based attacks, and that the MTD³L design offers similar security to the D³L design while requiring much less area and energy consumption.

TABLE 8
TIMING ANALYSIS RESULTS

| | Correlation | Correct Key Guess |
|---|---|---|
| Design | Coefficient | Success/Failure |
| NCL | 0.400 | Success |
| D³L | 0.337 | Failure |
| MTD³L | 0.366 | Failure |

Some concepts of MTD³L are described in Michael Linder, “MTD³L—A Low Overhead Secure IC Design Methodology” MS Thesis, Department of Computer Science & Computer Engineering, University of Arkansas, August 2011, the contents of which are hereby incorporated by reference.

What is claimed is:

1. A Multi-Threshold Dual-spacer Dual-rail Delay-insensitive Logic (MTD³L) circuit comprising:
a first circuit coupled to V_{DD};
a second circuit coupled to ground and the first circuit, the coupling to the first circuit forming a common coupling;
a first pmos transistor having a source coupled to V_{DD} and a gate coupled to a sleep-to-0 input;
a first nmos transistor having a drain coupled to ground and a gate coupled to a complement of a sleep-to-1 input;
a second pmos transistor having a source coupled to a drain of the first pmos transistor and a gate coupled to the common coupling;
a second nmos transistor having a drain coupled to a source of the first nmos transistor and a gate coupled to the common coupling;
a third pmos transistor having a source coupled to the drain of the first pmos transistor and a gate coupled to the complement of the sleep-to-1 input;
a third nmos transistor having a drain coupled to the source of the first nmos transistor and a gate coupled to the sleep-to-0 input; and
an output coupled to a drain of the second pmos transistor, a drain of the third pmos transistor, a source of the second nmos transistor, and a source of the third nmos transistor.

2. The MTD³L circuit of claim 1, wherein the first circuit is a Hold0 circuit.

3. The MTD³L circuit of claim 1, wherein the second circuit is a Set circuit.

4. The MTD³L circuit of claim 1, wherein the first circuit includes a pmos transistor having a source coupled to V_{DD}, a gate coupled to the sleep-to-1 input, and a drain coupled to a Hold0 circuit.

5. The MTD³L circuit of claim 1, wherein the second circuit includes a nmos transistor having a drain coupled to ground, a gate coupled to the complement of the sleep-to-0 input, and a source coupled to a Set circuit.

6. The MTD³L circuit of claim 1, wherein the output is an All-One Spacer when the sleep-to-0 input is a zero and the sleep-to-1 input is one.

7. The MTD³L circuit of claim 1, wherein the output is an All-Zero Spacer when the sleep-to-0 input is a one and the sleep-to-1 input is zero.

8. A Multi-Threshold Dual-spacer Dual-rail Delay-insensitive Logic (MTD³L) register, the register comprising:
a first th22 circuit configured to receive a first rail input, a completion detection signal, and a reset signal, and to produce a first rail output;
a second th22 circuit configured to receive a second rail input, the completion detection signal, and the reset signal, and to produce a second rail output; and
a XNOR gate configured to receive the first rail input and the second rail input and to produce a completion detection signal output.

9. The MTD³L register of claim 8, wherein the completion detection signal output is one when the reset signal is a NULL.

10. The MTD³L register of claim 8, wherein the completion detection signal output is DATA when the reset signal is a zero.

11. The MTD³L register of claim 8, wherein when the first rail input is the same as the second rail input, the MTD³L register has received a spacer, and the completion detection signal output requests data.

12. The MTD³L register of claim 8, wherein when the first rail input is not the same as the second rail input, the MTD³L register has received data, and the completion detection signal output requests a spacer.

13. A Complete Multi-Threshold Dual-spacer Dual-rail Delay-insensitive Logic (MTD³L) register configured to use dual-spacer protocol and early completion checking, the Complete MTD³L register comprising:
an MTD³L register configured to receive a first rail input and a second rail input and to generate a first rail output and a second rail output, the MTD³L register also configured to receive an internal completion detection signal (Ki_gen) and to generate an MTD³L register completion detection signal output;
a first th22 circuit configured to receive the first rail output and the second rail output, and to generate a previous spacer (ps) output;
a second th22 circuit configured to receive a complemented external completion detection signal and the MTD³L register completion detection signal output, and to generate a completion detection output (Ko); and
a completion detection generator (KiGen) configured to receive the first rail output and the second rail output, the ps, and an inverted form of the completion detection output, and to generate the internal completion detection signal (Ki_gen).

14. The Complete MTD³L register of claim 13, further comprising a plurality of gates configured to receive the completion detection output and generate a first sleep signal (s0) and a second sleep signal (s1).

15. The Complete MTD³L register of claim 13, wherein the MTD³L register includes:
a first th22 circuit configured to receive a first rail input, a completion detection generator signal, and a reset signal, and to produce a first rail output,
a second th22 circuit configured to receive a second rail input, the completion detection signal, and the reset signal, and to produce a first rail output, and
a XNOR gate configured to receive the first rail input and the second rail input and to produce a completion detection generator signal output.

16. The Complete MTD³L register of claim 13, wherein Ko is inverted before being received by the KiGen to ensure input-completeness.

17. The Complete MTD³L register of claim 16, wherein input-completeness prevents a partial spacer wavefront from passing through the Complete MTD³L register by ensuring that all of the Complete MTD³L register's inputs are an all-zero or an all-one spacer before the spacer wavefront is allowed to pass through the Complete MTD³L register.

18. The Complete MTD³L register of claim 13 wherein when a spacer is requested, an all-one spacer is requested when Ki_gen is a logic one, and an all-zero spacer is requested when Ki_gen is a logic zero.
